(19) United States
(12) Patent Application Publication
(10) Pub. No.: US 2025/0358947 A1
(43) Pub. Date: Nov. 20, 2025

(54) DISPLAY DEVICE

(71) Applicant: Samsung Display Co., LTD., Yongin-si (KR)

(72) Inventors: Min Sung KIM, Yongin-si (KR); Jung Il LEE, Yongin-si (KR); Joong Gun CHONG, Yongin-si (KR)

(21) Appl. No.: 19/038,480

(22) Filed: Jan. 27, 2025

(30) Foreign Application Priority Data
May 20, 2024 (KR) 10-2024-0065052

(51) Int. Cl. H05K 5/03

(52) U.S. Cl. CPC H05K 5/03

(57) ABSTRACT

Provided is a display device including a display panel including a folding area, and a first non-folding area and a second non-folding area on respective sides of the folding area, a lower protective film below a surface of the display panel, a support plate below the lower protective film, and including a first support plate in the first non-folding area, and a second support plate in the second non-folding area, and defining a first separation space between the first support plate and the second support plate, a first adhesive layer between the lower protective film and the support plate, and including a first sub-adhesive layer overlapping the first support plate, and a second sub-adhesive layer overlapping the second support plate, and defining a second separation space between the first sub-adhesive layer and the second sub-adhesive layer, and a step compensation film in the first separation space and in the second separation space.

### CROSS-REFERENCE TO RELATED APPLICATION

The present application claims priority to, and the benefit of, Korean Patent Application No. 10-2024-0065052, filed on May 20, 2024, in the Korean Intellectual Property Office, the entire disclosure of which is incorporated herein by reference.

### BACKGROUND

### 1. Field

The present disclosure relates to a display device.

### 2. Description of the Related Art

As the information society develops, demands for display devices for displaying images are increasing in various forms. The display devices may be liquid crystal displays, field emission displays, and light-emitting displays. The light-emitting displays include an organic light-emitting display including an organic light-emitting diode element as a light-emitting element and an inorganic light-emitting display including an inorganic light-emitting diode element as a light-emitting element.

To increase portability of a display device while providing a wide display screen, a bendable display device whose display area can be bent, or a foldable display device whose display area can be folded, have been released recently.

### SUMMARY

Aspects of the present disclosure provide a display device that can improve creasing and sagging phenomena.

Aspects of the present disclosure also provide a display device that reduces or minimizes introduction of foreign substances.

However, aspects of the present disclosure are not restricted to the one set forth herein. The above and other aspects of the present disclosure will become more apparent to one of ordinary skill in the art to which the present disclosure pertains by referencing the detailed description of the present disclosure given below.

According to an aspect of the present disclosure, there is provided a display device including a display panel including a folding area, and a first non-folding area and a second non-folding area on respective sides of the folding area, a lower protective film below a surface of the display panel, a support plate below the lower protective film, and including a first support plate in the first non-folding area, and a second support plate in the second non-folding area, and defining a first separation space between the first support plate and the second support plate, a first adhesive layer between the lower protective film and the support plate, and including a first sub-adhesive layer overlapping the first support plate, and a second sub-adhesive layer overlapping the second support plate, and defining a second separation space between the first sub-adhesive layer and the second sub-adhesive layer, and a step compensation film in the first separation space and in the second separation space.

A width of the step compensation film may be less than a width of the first separation space, and is less than a width of the second separation space.

The width of the step compensation film may be about 7 mm or less.

The width of the first separation space may be less than the width of the second separation space.

The width of the first separation space may be about 1 mm to about 7 mm.

The width of the second separation space may be about 5 mm to about 15 mm.

A difference between the width of the second separation space and the width of the first separation space may be about 5 mm or less.

A difference between the width of the first separation space and the width of the step compensation film may be about 1 mm or less.

A thickness of the step compensation film may be about 0.8 times to about 1.2 times a sum of a thickness of the first adhesive layer and a thickness of the support plate.

A difference between the thickness of the step compensation film and a sum of the thickness of the first adhesive layer and the thickness of the support plate may be about 50 mm or less.

An elastic modulus of the step compensation film may be about 1 GPa or less.

The display device may further include an upper module above the first adhesive layer, and including the display panel and the lower protective film,

wherein a width of the second separation space is greater than or equal to a value obtained by multiplying a radius of curvature of the upper module by pi.

The radius of curvature of the upper module may be about 1.5 mm to about 2 mm.

The display device may further include a lower anti-view layer above the support plate and in the folding area, and a second adhesive layer between the lower anti-view layer and the step compensation film.

The step compensation film may be bonded to the lower anti-view layer through the second adhesive layer.

An upper surface of the step compensation film may be spaced apart from a lower surface of the lower protective film.

The display device may further include a third adhesive layer between the lower protective film and the step compensation film for bonding the step compensation film to the lower protective film.

A lower surface of the step compensation film may be spaced apart from an upper surface of the second adhesive layer.

The step compensation film may include a first portion in the first separation space, and a second portion in the second separation space, wherein a direction in which the first portion extends is different from a direction in which the second portion extends wherein width of the first portion may be less than a width of the second portion.

According to an aspect of the present disclosure, there is provided an electronic device comprising a display device, the display device comprising, a display panel comprising a folding area, and a first non-folding area and a second non-folding area on respective sides of the folding area, a lower protective film below a surface of the display panel, a support plate below the lower protective film, and comprising a first support plate in the first non-folding area, and a second support plate in the second non-folding area, and defining a first separation space between the first support plate and the second support plate, a first adhesive layer between the lower protective film and the support plate, and comprising a first sub-adhesive layer overlapping the first support plate, and a second sub-adhesive layer overlapping the second support plate, and defining a second separation space between the first sub-adhesive layer and the second sub-adhesive layer, and a step compensation film in the first separation space and in the second separation space.

A display device according to one or more embodiments of the present disclosure can improve aspects associated with creasing and sagging phenomena.

A display device according to one or more embodiments of the present disclosure can reduce or minimize introduction of foreign substances.

However, the aspects of the present disclosure are not restricted to the one set forth herein. The above and other aspects of the present disclosure will become more apparent to one of daily skill in the art to which the present disclosure pertains by referencing the claims.

### BRIEF DESCRIPTION OF THE DRAWINGS

These and/or other aspects will become apparent and more readily appreciated from the following description of the embodiments, taken in conjunction with the accompanying drawings in which:

FIG. 1 is a perspective view illustrating an unfolded state of a display device according to one or more embodiments;

FIG. 2 is a perspective view illustrating a folded state of the display device according to the embodiment;

FIG. 3 is a perspective view illustrating an unfolded state of a display device according to one or more embodiments;

FIG. 4 is a perspective view illustrating a folded state of the display device according to the one or more embodiments corresponding to FIG. 3;

FIG. 5 is a cross-sectional view of a display device according to one or more embodiments;

FIG. 6 is a cross-sectional view of an example of a display panel according to one or more embodiments;

FIG. 7 is an enlarged view of an XA area of FIG. 5;

FIG. 8 is a cross-sectional view illustrating a folded state of the display device of FIG. 7;

FIG. 9 is a cross-sectional view of a part of a display device according to one or more embodiments;

FIG. 10 is a cross-sectional view illustrating a folded state of the display device of FIG. 9;

FIG. 11 is a cross-sectional view of a part of a display device according to one or more embodiments;

FIG. 12 is a cross-sectional view illustrating a folded state of the display device of FIG. 11;

FIG. 13 is a cross-sectional view of a part of a display device according to one or more embodiments;

FIG. 14 is a cross-sectional view of a part of a display device according to one or more embodiments; and

FIG. 15 is a cross-sectional view of a part of a display device according to one or more embodiments.

### DETAILED DESCRIPTION

Aspects of some embodiments of the present disclosure and methods of accomplishing the same may be understood more readily by reference to the detailed description of embodiments and the accompanying drawings. The described embodiments are provided as examples so that this disclosure will be thorough and complete, and will fully convey the aspects of the present disclosure to those skilled in the art. Accordingly, processes, elements, and techniques that are redundant, that are unrelated or irrelevant to the description of the embodiments, or that are not necessary to those having ordinary skill in the art for a complete understanding of the aspects of the present disclosure may be omitted. Unless otherwise noted, like reference numerals, characters, or combinations thereof denote like elements throughout the attached drawings and the written description, and thus, repeated descriptions thereof may be omitted.

The described embodiments may have various modifications and may be embodied in different forms, and should not be construed as being limited to only the illustrated embodiments herein. The use of “can,” “may,” or “may not” in describing an embodiment corresponds to one or more embodiments of the present disclosure.

A person of ordinary skill in the art would appreciate, in view of the
present disclosure in its entirety, that each suitable feature of the various embodiments
of the present disclosure may be combined or combined with each other, partially or
entirely, and may be technically interlocked and operated in various suitable ways, and
each embodiment may be implemented independently of each other or in conjunction
with each other in any suitable manner unless otherwise stated or implied.

In the drawings, the relative sizes of elements, layers, and regions may be exaggerated for clarity and/or descriptive purposes. In other words, because the sizes and thicknesses of elements in the drawings are arbitrarily illustrated for convenience of description, the disclosure is not limited thereto. Additionally, the use of cross-hatching and/or shading in the accompanying drawings is generally provided to clarify boundaries between adjacent elements. As such, neither the presence nor the absence of cross-hatching or shading conveys or indicates any preference or requirement for particular materials, material properties, dimensions, proportions, commonalities between illustrated elements, and/or any other characteristic, attribute, property, etc., of the elements, unless specified.

Various embodiments are described herein with reference to sectional illustrations that are schematic illustrations of embodiments and/or intermediate structures. As such, variations from the shapes of the illustrations as a result of, for example, manufacturing techniques and/or tolerances, are to be expected. Further, specific structural or functional descriptions disclosed herein are merely illustrative for the purpose of describing embodiments according to the concept of the present disclosure. Thus, embodiments disclosed herein should not be construed as limited to the illustrated shapes of elements, layers, or regions, but are to include deviations in shapes that result from, for instance, manufacturing.

For example, an implanted region illustrated as a rectangle will, typically, have rounded or curved features and/or a gradient of implant concentration at its edges rather than a binary change from implanted to non-implanted region. Likewise, a buried region formed by implantation may result in some implantation in the region between the buried region and the surface through which the implantation takes place.

Spatially relative terms, such as “beneath,” “below,” “lower,” “lower side,” “under,” “above,” “upper,” “over,” “higher,” “upper side,” “side” (e.g., as in “sidewall”), and the like, may be used herein for ease of explanation to describe one element or feature's relationship to another element(s) or feature(s) as illustrated in the figures. It will be understood that the spatially relative terms are intended to encompass different orientations of the device in use or in operation, in addition to the orientation depicted in the figures. For example, if the device in the figures is turned over, elements described as “below,” “beneath,” “or “under” other elements or features would then be oriented “above” the other elements or features. Thus, the example terms “below” and “under” can encompass both an orientation of above and below. The device may be otherwise oriented (e.g., rotated 90 degrees or at other orientations) and the spatially relative descriptors used herein should be interpreted accordingly. Similarly, when a first part is described as being arranged “on” a second part, this indicates that the first part is arranged at an upper side or a lower side of the second part without the limitation to the upper side thereof on the basis of the gravity direction.

Further, the phrase “in a plan view” means when an object portion is viewed from above, and the phrase “in a schematic cross-sectional view” means when a schematic cross-section taken by vertically cutting an object portion is viewed from the side. The terms “overlap” or “overlapped” mean that a first object may be above or below or to a side of a second object, and vice versa. Additionally, the term “overlap” may include stack, face or facing, extending over, covering, or partly covering or any other suitable term as would be appreciated and understood by those of ordinary skill in the art. The expression “not overlap” may include meaning, such as “apart from” or “set aside from” or “offset from” and any other suitable equivalents as would be appreciated and understood by those of ordinary skill in the art. The terms “face” and “facing” may mean that a first object may directly or indirectly oppose a second object. In a case in which a third object intervenes between a first and second object, the first and second objects may be understood as being indirectly opposed to one another, although still facing each other.

It will be understood that when an element, layer, region, or component (e.g.,

an apparatus, a device, a circuit, a wire, an electrode, a terminal, a conductive film, etc.) is referred to as being “formed on,” “on,” “connected to,” or “(operatively, functionally, or communicatively) coupled to” another element, layer, region, or component, it can be directly formed on, on, connected to, or coupled to the other element, layer, region, or component, or indirectly formed on, on, connected to, or coupled to the other element, layer, region, or component such that one or more intervening elements, layers, regions, or components may be present. In addition, this may collectively mean a direct or indirect coupling or connection and an integral or non-integral coupling or connection. For example, when a layer, region, or component is referred to as being “electrically connected” or “electrically coupled” to another layer, region, or component, it can be directly electrically connected or coupled to the other layer, region, and/or component or one or more intervening layers, regions, or components may be present. The one or more intervening components may include a switch, a transistor, a resistor, an inductor, a capacitor, a diode and/or the like. Accordingly, a connection is not limited to the connections illustrated in the drawings or the detailed description and may also include other types of connections. In describing embodiments, an expression of connection indicates electrical connection unless explicitly described to be direct connection, and “directly connected/directly coupled,” or “directly on,” refers to one component directly connecting or coupling another component, or being on another component, without an intermediate component.

In addition, in the present specification, when a portion of a layer, a film, an area, a plate, or the like is formed on another portion, a forming direction is not limited to an upper direction but includes forming the portion on a side surface or in a lower direction. On the contrary, when a portion of a layer, a film, an area, a plate, or the like is formed “under” another portion, this includes not only a case where the portion is “directly beneath” another portion but also a case where there is further another portion between the portion and another portion. Meanwhile, other expressions describing relationships between components, such as “between,” “immediately between” or “adjacent to” and “directly adjacent to,” may be construed similarly. It will be understood that when an element or layer is referred to as being “between” two elements or layers, it can be the only element or layer between the two elements or layers, or one or more intervening elements or layers may also be present.

For the purposes of this disclosure, expressions such as “at least one of,” or “any one of,” or “one or more of” when preceding a list of elements, modify the entire list of elements and do not modify the individual elements of the list. For example, “at least one of X, Y, and Z,” “at least one of X, Y, or Z,” “at least one selected from the group consisting of X, Y, and Z,” and “at least one selected from the group consisting of X, Y, or Z” may be construed as X only, Y only, Z only, any combination of two or more of X, Y, and Z, such as, for instance, XYZ, XYY, YZ, and ZZ, or any variation thereof. Similarly, the expressions “at least one of A and B” and “at least one of A or B” may include A, B, or A and B. As used herein, “or” generally means “and/or,” and the term “and/or” includes any and all combinations of one or more of the associated listed items. For example, the expression “A and/or B” may include A, B, or A and B.

Similarly, expressions such as “at least one of,” “a plurality of,” “one of,” and other prepositional phrases, when preceding a list of elements, modify the entire list of elements and do not modify the individual elements of the list. When “C to D” is stated, it means C or more and D or less, unless otherwise specified.

It will be understood that, although the terms “first,” “second,” “third,” etc., may be used herein to describe various elements, components, regions, layers and/or sections, these elements, components, regions, layers and/or sections should not be limited by these terms. These terms do not correspond to a particular order, position, or superiority, and are used only used to distinguish one element, member, component, region, area, layer, section, or portion from another element, member, component, region, area, layer, section, or portion. Thus, a first element, component, region, layer or section described below could be termed a second element, component, region, layer or section, without departing from the spirit and scope of the present disclosure. The description of an element as a “first” element may not require or imply the presence of a second element or other elements. The terms “first,” “second,” etc. may also be used herein to differentiate different categories or sets of elements. For conciseness, the terms “first,” “second,” etc. may represent “first-category (or first-set),” “second-category (or second-set),” etc., respectively.

In the examples, the x-axis, the y-axis, and/or the z-axis are not limited to three axes of a rectangular coordinate system, and may be interpreted in a broader sense. For example, the x-axis, the y-axis, and the z-axis may be perpendicular to one another, or may represent different directions that are not perpendicular to one another. The same applies for first, second, and/or third directions.

The terminology used herein is for the purpose of describing embodiments only and is not intended to be limiting of the present disclosure. As used herein, the singular forms “a” and “an” are intended to include the plural forms as well, while the plural forms are also intended to include the singular forms, unless the context clearly indicates otherwise. It will be further understood that the terms “comprises,” “comprising,” “have,” “having,” “includes,” and “including,” when used in this specification, specify the presence of the stated features, integers, steps, operations, elements, and/or components, but do not preclude the presence or addition of one or more other features, integers, steps, operations, elements, components, and/or groups thereof.

As used herein, the terms “substantially,” “about,” “approximately,” and similar terms are used as terms of approximation and not as terms of degree, and are intended to account for the inherent deviations in measured or calculated values that would be recognized by those of ordinary skill in the art. For example, “substantially” may include a range of +/−5% of a corresponding value. “About” or “approximately,” as used herein, is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” may mean within one or more standard deviations, or within ±30%, 20%, 10%, 5% of the stated value. Further, the use of “may” when describing embodiments of the present disclosure refers to “one or more embodiments of the present disclosure.”

Unless otherwise defined, all terms (including technical and scientific terms) used herein have the same meaning as commonly understood by one of ordinary skill in the art to which the present disclosure belongs. It will be further understood that terms, such as those defined in commonly used dictionaries, should be interpreted as having a meaning that is consistent with their meaning in the context of the relevant art and/or the present specification, and should not be interpreted in an idealized or overly formal sense, unless expressly so defined herein.

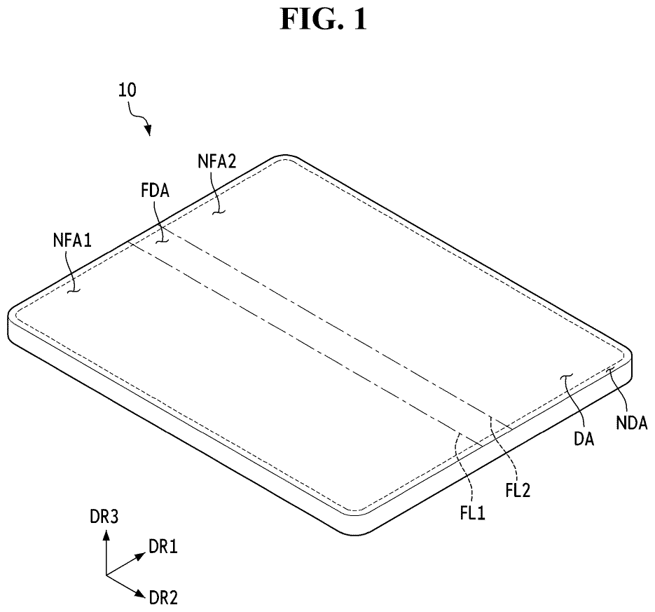

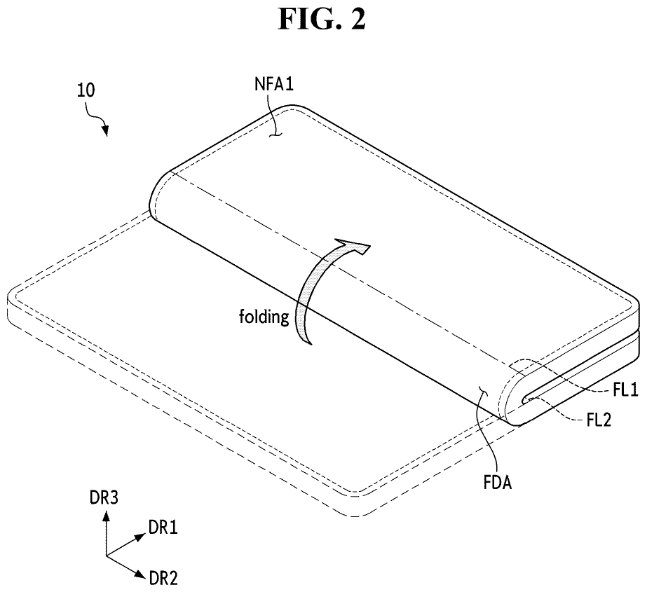

FIG. 1 is a perspective view illustrating an unfolded state of a display device 10 according to one or more embodiments. FIG. 2 is a perspective view illustrating a folded state of the display device 10.

Referring to FIGS. 1 and 2, FIG. 1 illustrates a first state in which the display device 10 is not folded at folding lines FL1 and FL2, and FIG. 2 illustrates a second state in which the display device 10 is folded at the folding lines FL1 and FL2.

The display device 10 may be a foldable display device. Although a case where the display device 10 is applied to a smartphone is mainly described, the present disclosure is not limited thereto. For example, a display device 10 according to embodiments of the present specification is a device for displaying moving images or still images. The display device 10 may be used as a display screen in portable electronic devices, such as mobile phones, smartphones, tablet personal computers (PCs), smart watches, watch phones, mobile communication terminals, electronic notebooks, electronic books, portable multimedia players (PMPs), navigation devices and ultra-mobile PCs (UMPCs), as well as in various products, such as televisions, notebook computers, monitors, billboards and Internet of things (IoT) devices.

The display device 10 according to the embodiments may be variously classified according to a display method. For example, the display device 10 may be an organic light-emitting display device, an inorganic light-emitting display device, a quantum dot light-emitting display device, a micro-light-emitting diode display device, a nano-light-emitting diode display device, a field emission display device, or an electrophoretic display device. An organic light-emitting display device will be described below as an example of the display device 10. Unless a special distinction is suitable, the organic light-emitting display device applied to embodiments will be shortened to the display device 10. However, embodiments are not limited to the organic light-emitting display device, and other display devices listed above or known in the art can also be applied within the scope sharing the technical spirit.

In the drawings, a first direction DR1 may be a direction parallel to a side of the display device 10 in plan view, for example, may be a horizontal direction of the display device 10. A second direction DR2 may be a direction parallel to another side in contact with the above side of the display device 10 in plan view, for example, may be a vertical direction of the display device 10. A third direction DR3 may be a thickness direction of the display device 10.

The first direction DR1 and the second direction DR2 are horizontal directions and may cross each other. For example, the first direction DR1 and the second direction DR2 may be orthogonal to each other. In addition, the third direction DR3 may be a vertical direction crossing the first direction DR1 and the second direction DR2, for example, orthogonal to the first direction DR1 and the second direction DR2. Unless otherwise defined, in the present specification, a direction indicated by an arrow of each of the first through third directions DR1 through DR3 may be referred to as a first side, and the opposite direction may be referred to as a second side. In addition, in the present specification, “on,” “upper side,” “above,” “top,” and “upper surface” refer to a direction in which an arrow of the third direction DR3 points in the drawings, and “under,” “lower side,” “below,” “bottom,” and “lower surface” refer to a direction opposite to the direction in which the arrow of the third direction DR3 points in the drawings.

The display device 10 may have a rectangular or square shape in plan view. However, the present disclosure is not limited thereto, and in some embodiments, the display device 10 may have a rectangular shape with vertical corners or a rectangular shape with rounded corners in plan view. The display device 10 may include two short sides in the first direction DR1, and two long sides in the second direction DR2 in plan view.

The display device 10 includes a display area DA and a non-display area NDA. The shape of the display area DA may correspond to the shape of the display device 10 in plan view. For example, when the display device 10 is rectangular in plan view, the display area DA may also be rectangular in plan view.

The display area DA may be an area that includes a plurality of pixels to display an image. The pixels may be arranged in a matrix direction. The pixels may have a rectangular, rhombic, or square shape in plan view, but the present disclosure is not limited thereto. For example, the pixels may also have a quadrangular shape other than the rectangular, rhombic or square shape, a polygonal shape other than the quadrangular shape, a circular shape, or an oval shape in plan view.

The non-display area NDA may be an area that does not include pixels, and thus does not display an image. The non-display area NDA may be located around the display area DA. The non-display area NDA may surround the display area DA (e.g., in plan view) as illustrated in FIGS. 1 and 2. However, the present disclosure is not limited thereto. The display area DA may also be partially surrounded by the non-display area NDA.

The display device 10 may maintain both the first state that is the unfolded state, and the second state that is the folded state. The display device 10 may be folded in an in-folding manner in which portions of the display area DA face each other and are placed inside as illustrated in FIG. 2. When the display device 10 is folded in the in-folding manner, portions of a front surface of the display device 10 may face each other. Alternatively, the display device 10 may be folded in an out-folding manner in which portions of the display area DA are located on opposite sides and placed outside. When the display device 10 is folded in the out-folding manner, portions of a back surface of the display device 10 may face each other.

The display device 10 may include a folding area FDA, a first non-folding area NFA1, and a second non-folding area NFA2. The folding area FDA may be an area in which the display device 10 is bent or folded. The first non-folding area NFA1 and the second non-folding area NFA2 may be areas in which the display device 10 is not bent or folded. In one or more embodiments, the first non-folding area NFA1 and the second non-folding area NFA2 may be, but are not limited to, flat areas of the display device 10.

The first non-folding area NFA1 may be located on a side (e.g., a left side) of the folding area FDA. The second non-folding area NFA2 may be located on the other side (e.g., a right side) of the folding area FDA. Here, the left side may refer to the second side in the first direction DR1, and the right side may refer to the first side in the first direction DR1.

The folding area FDA may be an area that is defined by a first folding line FL1 and a second folding line FL2 and an area in which the display device 10 is bent with a curvature (e.g., predetermined curvature). The first folding line FL1 may be a boundary between the folding area FDA and the first non-folding area NFA1, and the second folding line FL2 may be a boundary between the folding area FDA and the second non-folding area NFA2.

As illustrated in FIGS. 1 and 2, the first folding line FL1 and the second folding line FL2 may extend in the second direction DR2. In this case, the display device 10 may be folded along the first direction DR1. Therefore, because a length of the display device 10 in the first direction DR1 can be reduced by about half, a user can easily carry the display device 10.

When the first folding line FL1 and the second folding line FL2 extend in the second direction DR2, a length of the folding area FDA in the second direction DR2 may be greater than a length of the folding area FDA in the first direction DR1. In addition, a length of the first non-folding area NFA1 in the second direction DR2 may be greater than a length of the first non-folding area NFA1 in the first direction DR1. A length of the second non-folding area NFA2 in the second direction DR2 may be greater than a length of the second non-folding area NFA2 in the first direction DR1.

Each of the display area DA and the non-display area NDA may overlap at least one of the folding area FDA, the first non-folding area NFA1, or the second non-folding area NFA2. In FIGS. 1 and 2, each of the display area DA and the non-display area NDA overlaps the folding area FDA, the first non-folding area NFA1, and the second non-folding area NFA2.

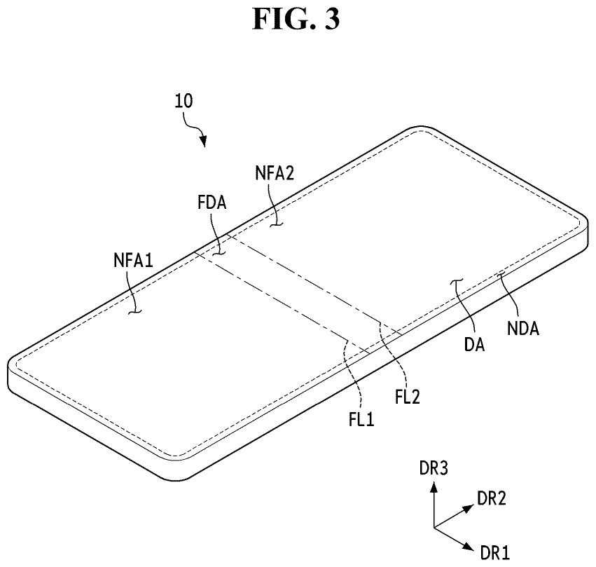

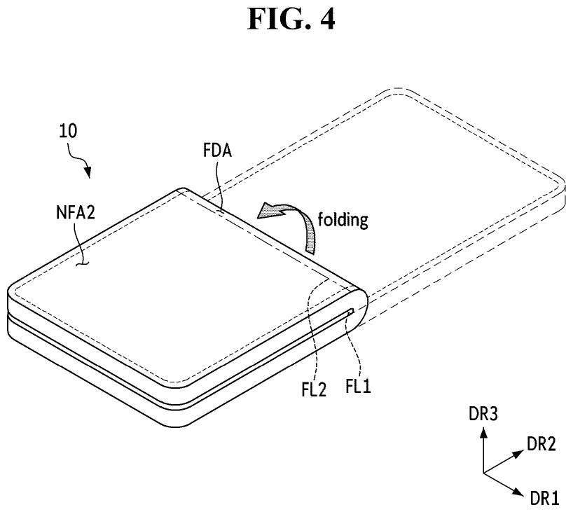

FIG. 3 is a perspective view illustrating an unfolded state of a display device 10 according to one or more embodiments. FIG. 4 is a perspective view illustrating a folded state of the display device 10.

Referring to FIGS. 3 and 4, FIG. 3 illustrates a first state in which the display device 10 is not folded at folding lines FL1 and FL2, and FIG. 4 illustrates a second state in which the display device 10 is folded at the folding lines FL1 and FL2.

In the first state in which the display device 10 is unfolded, long sides of the display device 10 may extend along the second direction DR2, and short sides of the display device 10 may extend along the first direction DR1.

In the display device 10 according to the one or more embodiments corresponding to FIGS. 3 and 4, a first folding line FL1 and a second folding line FL2 may extend in the first direction DR1, and the display device 10 may be folded along the second direction DR2.

A first non-folding area NFA1 may be located on a side (e.g., a lower side) of a folding area FDA. A second non-folding area NFA2 may be located on the other side (e.g., an upper side) of the folding area FDA. Here, the upper side may refer to the first side in the second direction DR2, and the lower side may refer to the second side in the second direction DR2.

As illustrated in FIGS. 3 and 4, when the first folding line FL1 and the second folding line FL2 extend in the first direction DR1, a length of the folding area FDA in the first direction DR1 may be greater than a length of the folding area FDA in the second direction DR2. In addition, a length of the first non-folding area NFA1 in the second direction DR2 may be greater than a length of the first non-folding area NFA1 in the first direction DR1. A length of the second non-folding area NFA2 in the second direction DR2 may be greater than a length of the second non-folding area NFA2 in the first direction DR1.

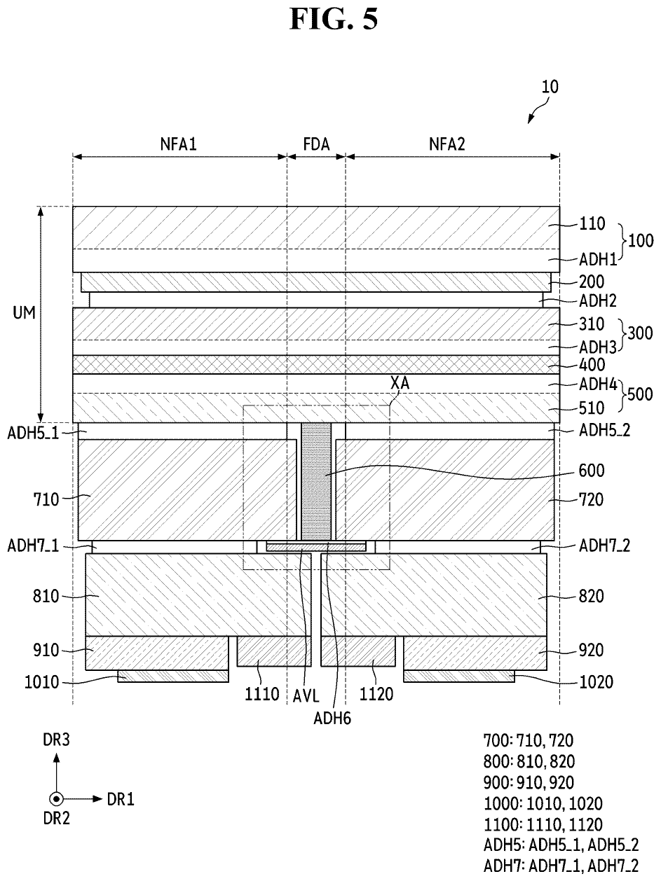

FIG. 5 is a cross-sectional view of a display device 10 according to one or more embodiments.

Referring to FIG. 5, the display device 10 may include a first upper protective film 100, a window 200, a second adhesive layer ADH2, a second upper protective film 300, a display panel 400, a lower protective film 500, a fifth adhesive layer ADH5 (e.g., a first adhesive layer in the claims), a step compensation film 600, a support plate 700, a sixth adhesive layer ADH6 (e.g., a second adhesive layer in the claims), a lower anti-view layer AVL, a seventh adhesive layer ADH7, a digitizer 800, a shielding layer 900, a heat dissipation layer 1000, and a buffer layer 1100.

The display panel 400 may be a panel that displays an image. The display panel 400 may be an organic light-emitting display panel including an organic light-emitting layer, a quantum dot light-emitting display panel including a quantum dot light-emitting layer, an inorganic light-emitting display panel using an inorganic semiconductor element as a light-emitting element, or a micro-light-emitting display panel using a micro-light-emitting diode as a light-emitting element. A case where the display panel 400 is an organic light-emitting display panel will be mainly described below, but the present disclosure is not limited thereto.

The first upper protective film 100 may be located on a surface of the display panel 400. For example, the first upper protective film 100 may be located on an upper surface of the display panel 400 (as used herein, “located on” may mean “above,” or may mean “below”). The first upper protective film 100 may include a first upper protective layer 110 and a first adhesive layer ADH1.

The first upper protective layer 110 may perform at least one of the functions of shock absorption, scratch prevention/reduction, fingerprint prevention/reduction, glare prevention/reduction, or shatter prevention/reduction of the window 200. The first upper protective layer 110 may include a material having high flexibility and/or high scratch resistance. For example, the first upper protective layer 110 may be a polymer film, such as polyethylene terephthalate or a tempered glass film.

The first upper protective layer 110 may include a coating layer located on an upper surface of the first upper protective layer 110. The coating layer may be a low-reflection and anti-fingerprint (LRAF) coating layer.

The first adhesive layer ADH1 may be located under the first upper protective layer 110. For example, the first adhesive layer ADH1 may be located between the first upper protective layer 110 and the window 200. The first upper protective layer 110 and the window 200 may be bonded to each other through the first adhesive layer ADH1. The first adhesive layer ADH1 may include a pressure sensitive adhesive or a transparent adhesive, such as an optically clear adhesive. Alternatively, the first adhesive layer ADH1 may include an acrylic adhesive material.

The first adhesive layer ADH1 may be handled while attached to the first upper protective layer 110 during a process of storage, transportation, etc. of the first upper protective film 100. A release film may be placed on a lower surface of the first adhesive layer ADH1 before the first adhesive layer ADH1 is attached to the window 200. The release film may remain attached to the lower surface of the first adhesive layer ADH1 while the first upper protective film 100 is handled, and may be removed when the first adhesive layer ADH1 is attached to the window 200.

The window 200 may be located on the surface of the display panel 400. The window 200 may be located between the first upper protective film 100 and the display panel 400. The window 200 may be located under the first upper protective film 100.

The window 200 may protect the display panel 400 from external impact. The window 200 may enhance the impact resistance of the display device 10. The window 200 may be made of a transparent material. For example, the window 200 may be glass or plastic. In some embodiments, the window 200 may be ultra-thin glass (UTG) having a thickness of about 0.1 mm or less. Alternatively, the window 200 may be a transparent polyimide film.

The second adhesive layer ADH2 may be located under the window 200. For example, the second adhesive layer ADH2 may be located between the window 200 and the second upper protective film 300. The window 200 and the second upper protective film 300 may be bonded to each other through the second adhesive layer ADH2. The second adhesive layer ADH2 may include a pressure sensitive adhesive or a transparent adhesive, such as an optically clear adhesive. Alternatively, the second adhesive layer ADH2 may include an acrylic adhesive material.

The second upper protective film 300 may be located on the surface of the display panel 400. For example, the second upper protective film 300 may be located on the upper surface of the display panel 400. The second upper protective film 300 may include a second upper protective layer 310 and a third adhesive layer ADH3.

The second upper protective layer 310 may perform a shock-absorbing function to protect the display panel 400 from external impact. The second upper protective layer 310 may include a material having high flexibility and high rigidity. For example, the second upper protective layer 310 may be a polymer film, such as polyethylene terephthalate (PET) or polyimide. Accordingly, the display device 10 may have high impact resistance to external impact.

The third adhesive layer ADH3 may be located under the second upper protective layer 310. For example, the third adhesive layer ADH3 may be located between the second upper protective layer 310 and the display panel 400. The second upper protective layer 310 and the display panel 400 may be bonded to each other through the third adhesive layer ADH3. The third adhesive layer ADH3 may include a pressure sensitive adhesive or a transparent adhesive, such as an optically clear adhesive. Alternatively, the third adhesive layer ADH3 may include an acrylic adhesive material.

The third adhesive layer ADH3 may be handled while attached to the second upper protective layer 310 during a process of storage, transportation, etc. of the second upper protective film 300. A release film may be placed on a lower surface of the third adhesive layer ADH3 before the third adhesive layer ADH3 is attached to the display panel 400. The release film may remain attached to the lower surface of the third adhesive layer ADH3 while the second upper protective film 300 is handled and may be removed when the third adhesive layer ADH3 is attached to the display panel 400.

The lower protective film 500 may be located on the other surface of the display panel 400. For example, the lower protective film 500 may be located on a lower surface of the display panel 400. The lower protective film 500 may include a lower protective layer 510 and a fourth adhesive layer ADH4.

The lower protective layer 510 may support the display panel 400, and may protect the other surface of the display panel 400. In some embodiments, the lower protective layer 510 may be a polymer film, such as polyethylene terephthalate (PET) or polyimide.

The fourth adhesive layer ADH4 may be located on the lower protective layer 510. For example, the fourth adhesive layer ADH4 may be located between the lower protective layer 510 and the display panel 400. The lower protective layer 510 and the display panel 400 may be bonded to each other through the fourth adhesive layer ADH4. The fourth adhesive layer ADH4 may include a pressure sensitive adhesive or a transparent adhesive, such as an optically clear adhesive. Alternatively, the fourth adhesive layer ADH4 may include an acrylic adhesive material.

The fourth adhesive layer ADH4 may be handled while attached to the lower protective layer 510 during a process of storage, transportation, etc. of the lower protective film 500. A release film may be placed on an upper surface of the fourth adhesive layer ADH4 before the fourth adhesive layer ADH4 is attached to the display panel 400. The release film may remain attached to the upper surface of the fourth adhesive layer ADH4 while the lower protective film 500 is handled and may be removed when the fourth adhesive layer ADH4 is attached to the display panel 400.

In some embodiments, the first upper protective film 100, the window 200, the second adhesive layer ADH2, the second upper protective film 300, the display panel 400, and the lower protective film 500 may be included in an upper module UM. The upper module UM may be located on the fifth adhesive layer ADH5.

The support plate 700 may be located under the lower protective film 500. The support plate 700 may be a rigid member that is not easily changed in shape or volume by external pressure. Because the support plate 700 is located on the other surface of the display panel 400, and is a rigid member that is not easily changed in shape or volume by external pressure, the support plate 700 can support the display panel 400.

In one or more embodiments, the support plate 700 may be a metal plate. For example, the support plate 700 may be a metal plate made of a metal or a metal alloy. The support plate 700 may include, but is not limited to, copper (Cu), aluminum (Al), stainless steel (SUS), and/or an alloy thereof.

In one or more embodiments, the support plate 700 may be a polymer including carbon fibers or glass fibers. In this case, because the support plate 700 is made of a polymer including carbon fibers or glass fibers, the support plate 700 may allow an electromagnetic signal of a digitizer member to pass therethrough when the display device 10 includes the digitizer member under the support plate 700. Therefore, it is possible to provide the support plate 700 that can support the display panel 400 while not lowering the touch sensitivity of the digitizer member.

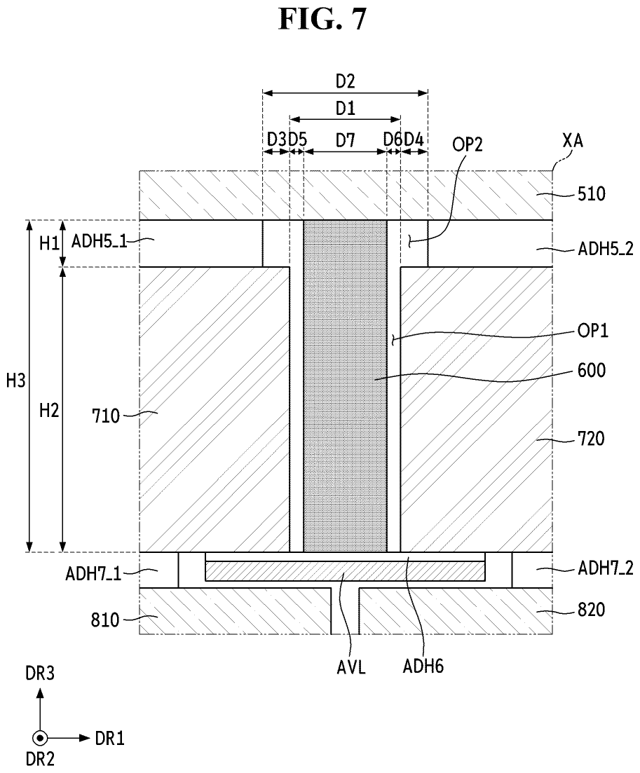

The support plate 700 may be configured as a separable plate so that the support plate 700 can be easily bent in a folding area FDA. For example, the support plate 700 may include a first separation space OP1 (see FIG. 7) in the folding area FDA. Because the support plate 700 includes the first separation space OP1 (see FIG. 7) located in the folding area FDA, the stress applied when the display device 10 is folded can be reduced or minimized.

In some embodiments, the support plate 700 may include a first support plate 710 located in a first non-folding area NFA1, and a second support plate 720 located in a second non-folding area NFA2. The first support plate 710 and the second support plate 720 may be spaced apart from each other in the horizontal direction (e.g., the first direction DR1). The first separation space OP1 (see FIG. 7) may be located between the first support plate 710 and the second support plate 720. In the drawing, each of the first support plate 710 and the second support plate 720 overlaps at least a portion of the folding area FDA. However, the present disclosure is not limited thereto. The first support plate 710 and the second support plate 720 may also be located only in the first non-folding area NFA1 and the second non-folding area NFA2, respectively, without overlapping the folding area FDA.

The fifth adhesive layer ADH5 may be located on the support plate 700. For example, the fifth adhesive layer ADH5 (e.g., the first adhesive layer in the claims) may be located between the support plate 700 and the lower protective film 500. The support plate 700 and the lower protective film 500 may be bonded to each other through the fifth adhesive layer ADH5. The fifth adhesive layer ADH5 may include a pressure sensitive adhesive or a transparent adhesive, such as an optically clear adhesive. Alternatively, the fifth adhesive layer ADH5 may include an acrylic adhesive material.

In some embodiments, the fifth adhesive layer ADH5 may be omitted from the folding area FDA and may be located only in the non-folding areas NFA1 and NFA2. Accordingly, the stress applied when the display device 10 is folded can be reduced or minimized. For example, the fifth adhesive layer ADH5 may include a first sub-adhesive layer ADH5_1 located in the first non-folding area NFA1, and a second sub-adhesive layer ADH5_2 located in the second non-folding area NFA2.

The first sub-adhesive layer ADH5_1 may be located on the first support plate 710, and the second sub-adhesive layer ADH5_2 may be located on the second support plate 720. The first sub-adhesive layer ADH5_1 and the second sub-adhesive layer ADH5_2 may be spaced apart from each other in the horizontal direction (e.g., the first direction DR1). The fifth adhesive layer ADH5 may include a second separation space OP2 (see FIG. 7) located between the first sub-adhesive layer ADH5_1 and the second sub-adhesive layer ADH5_2. The second separation space OP2 (see FIG. 7) of the fifth adhesive layer ADH5 may be located in the folding area FDA. The second separation space OP2 (see FIG. 7) of the fifth adhesive layer ADH5 may overlap the first separation space OP1 (see FIG. 7) of the support plate 700 in the third direction DR3.

The step compensation film 600 may be located on a back surface of the lower protective film 500. For example, the step compensation film 600 may be located between the lower protective film 500 and the lower anti-view layer AVL in the third direction DR3.

The step compensation film 600 may be located in the folding area FDA. The step compensation film 600 may be located in the first separation space OP1 (see FIG. 7) of the support plate 700 and in the second separation space OP2 (see FIG. 7) of the fifth adhesive layer ADH5. For example, the step compensation film 600 may be located between the first support plate 710 and the second support plate 720, and between the first sub-adhesive layer ADH5_1 and the second sub-adhesive layer ADH5_2 in the horizontal direction (e.g., the first direction DR1).

The step compensation film 600 may extend in the third direction DR3. The step compensation film 600 may penetrate the first separation space OP1 (see FIG. 7) of the support plate 700 and the second separation space OP2 (see FIG. 7) of the fifth adhesive layer ADH5.

The step compensation film 600 may serve as a support for reducing or preventing sagging of the display panel 400 or the upper module UM or creasing of the folding area FDA due to the first separation space OP1 (see FIG. 7) of the support plate 700 and the second separation space OP2 (see FIG. 7) of the fifth adhesive layer ADH5.

The step compensation film 600 may include a flexible material to reduce or minimize the stress applied when the display device 10 is folded. For example, the step compensation film 600 may include a thermoplastic polyurethane (TPU) material.

The lower anti-view layer AVL may be located on a back surface of the support plate 700. The lower anti-view layer AVL may overlap the folding area FDA. The lower anti-view layer AVL may be located on the same layer as the seventh adhesive layer ADH7. The lower anti-view layer AVL may be located between a third sub-adhesive layer ADH7-1 and a fourth sub-adhesive layer ADH7-2, which will be described later. The lower anti-view layer AVL may reduce or prevent visibility of the first separation space OP1 (see FIG. 7) of the support plate 700, the second separation space OP2 (see FIG. 7) of the fifth adhesive layer ADH5, and other members located under the display panel 400 (e.g., visibility from the outside). The lower anti-view layer AVL may include a flexible material to reduce the folding stress of the display device 10. For example, the lower anti-view layer AVL may include a thermoplastic polyurethane (TPU) material.

The sixth adhesive layer ADH6 may be located on the lower anti-view layer AVL. For example, the sixth adhesive layer ADH6 (e.g., the second adhesive layer in the claims) may be located between the lower anti-view layer AVL and the support plate 700. The lower anti-view layer AVL and the support plate 700 may be bonded to each other through the sixth adhesive layer ADH6. The sixth adhesive layer ADH6 may include a pressure sensitive adhesive or a transparent adhesive, such as an optically clear adhesive. Alternatively, the sixth adhesive layer ADH6 may include an acrylic adhesive material.

In some embodiments, the sixth adhesive layer ADH6 may be located between the step compensation film 600 and the lower anti-view layer AVL. The step compensation film 600 and the lower anti-view layer AVL may be bonded to each other by the sixth adhesive layer ADH6.

The digitizer 800 may be located on the back surface of the support plate 700. The digitizer 800 may be omitted from at least a portion of the folding area FDA to reduce the folding stress of the display device 10. For example, the digitizer 800 may include a separation space located in the folding area FDA.

The digitizer 800 may include electrode patterns for sensing the approach or touch of an electronic pen, such as a stylus pen that supports electromagnetic resonance (EMR). The digitizer 800 may sense a magnetic field or electromagnetic signal emitted from the electronic pen based on the electrode patterns, and may determine a point, at which the sensed magnetic field or electromagnetic signal is greatest, as touch coordinates.

The digitizer 800 may include a first digitizer 810 and a second digitizer 820. The first digitizer 810 may be located in the first non-folding area NFA1, and the second digitizer 820 may be located in the second non-folding area NFA2. A separation space between the first digitizer 810 and the second digitizer 820 may overlap the folding area FDA. A width of the separation space between the first digitizer 810 and the second digitizer 820 may be less than a width of the folding area FDA, but the present disclosure is not limited thereto.

The seventh adhesive layer ADH7 may be located on the digitizer 800. For example, the seventh adhesive layer ADH7 may be located between the support plate 700 and the digitizer 800. The support plate 700 and the digitizer 800 may be bonded to each other through the seventh adhesive layer ADH7. The seventh adhesive layer ADH7 may include a pressure sensitive adhesive or a transparent adhesive, such as an optically clear adhesive. Alternatively, the seventh adhesive layer ADH7 may include an acrylic adhesive material.

In some embodiments, the seventh adhesive layer ADH7 may be omitted from the folding area FDA, and may be located only in the non-folding areas NFA1 and NFA2. Accordingly, the stress applied when the display device 10 is folded can be reduced or minimized. For example, the seventh adhesive layer ADH7 may include the third sub-adhesive layer ADH7_1 located in the first non-folding area NFA1, and the fourth sub-adhesive layer ADH7_2 located in the second non-folding area NFA2.

The third sub-adhesive layer ADH7_1 may be located on the first digitizer 810, and the fourth sub-adhesive layer ADH7_2 may be located on the second digitizer 820. The third sub-adhesive layer ADH7_1 and the fourth sub-adhesive layer ADH7_2 may be spaced apart from each other in the horizontal direction (e.g., the first direction DR1). The seventh adhesive layer ADH7 may include a separation space located between the third sub-adhesive layer ADH7_1 and the fourth sub-adhesive layer ADH7_2. The separation space of the seventh adhesive layer ADH7 may be located in the folding area FDA.

The shielding layer 900 may be located on a back surface of the digitizer 800. The shielding layer 900 may include magnetic metal powder. Accordingly, a magnetic field or electromagnetic signal passing through the digitizer 800 may be made to flow into the shielding layer 900. Therefore, the shielding layer 900 can reduce the emission of the magnetic field or electromagnetic signal of the digitizer 800 from a back surface of the display device 10.

The shielding layer 900 may be omitted from the folding area FDA and may be located only in the non-folding areas NFA1 and NFA2. Accordingly, the stress applied when the display device 10 is folded can be reduced or minimized. For example, the shielding layer 900 may include a separation space located in the folding area FDA.

The shielding layer 900 may include a first shielding layer 910 and a second shielding layer 920. The first shielding layer 910 may be located on a back surface of the first digitizer 810, and the second shielding layer 920 may be located on a back surface of the second digitizer 820. The first shielding layer 910 may be located in the first non-folding area NFA1, and the second shielding layer 920 may be located in the second non-folding area NFA2. A separation space between the first shielding layer 910 and the second shielding layer 920 may overlap the folding area FDA. A width of the separation space between the first shielding layer 910 and the second shielding layer 920 may be greater than the width of the folding area FDA, but the present disclosure is not limited thereto.

The heat dissipation layer 1000 may be located on a back surface of the shielding layer 900. The heat dissipation layer 1000 may be a metal layer having excellent thermal conductivity, such as copper, nickel, ferrite, or silver. Accordingly, heat generated in the display device 10 may be released to the outside by the heat dissipation layer 1000.

The heat dissipation layer 1000 may be omitted from the folding area FDA and may be located only in the non-folding areas NFA1 and NFA2. Accordingly, the stress applied when the display device 10 is folded can be reduced or minimized. For example, the heat dissipation layer 1000 may include a separation space located in the folding area FDA.

The heat dissipation layer 1000 may include a first heat dissipation layer 1010 and a second heat dissipation layer 1020. The first heat dissipation layer 1010 may be located on a back surface of the first shielding layer 910, and the second heat dissipation layer 1020 may be located on a back surface of the second shielding layer 920. The first heat dissipation layer 1010 may be located in the first non-folding area NFA1, and the second heat dissipation layer 1020 may be located in the second non-folding area NFA2. A separation space between the first heat dissipation layer 1010 and the second heat dissipation layer 1020 may overlap the folding area FDA. A width of the separation space between the first heat dissipation layer 1010 and the second heat dissipation layer 1020 may be greater than the width of the folding area FDA, but the present disclosure is not limited thereto.

The buffer layer 1100 may be located on the back surface of the digitizer 800. The buffer layer 1100 may be located on the same layer as the shielding layer 900. The buffer layer 1100 may be located between the first shielding layer 910 and the second shielding layer 920.

The buffer layer 1100 may reduce or prevent damage to the support plate 700 and the digitizer 800 by absorbing external shock. The buffer layer 1100 may include an elastic material, such as a sponge formed by foaming rubber, a urethane-based material, or an acrylic-based material.

The buffer layer 1100 may be omitted from at least a portion of the folding area FDA to reduce the folding stress of the display device 10. For example, the buffer layer 1100 may include a separation space located in the folding area FDA.

The buffer layer 1100 may include a first buffer layer 1110 and a second buffer layer 1120. The first buffer layer 1110 may be located on the back surface of the first digitizer 810, and the second buffer layer 1120 may be located on the back surface of the second digitizer 820. The first buffer layer 1110 may be located in the first non-folding area NFA1, and the second buffer layer 1120 may be located in the second non-folding area NFA2. A separation space between the first buffer layer 1110 and the second buffer layer 1120 may overlap the folding area FDA. A width of the separation space between the first buffer layer 1110 and the second buffer layer 1120 may be less than the width of the folding area FDA, but the present disclosure is not limited thereto.

In the drawing, adhesive layers respectively between the digitizer 800 and the shielding layer 900, between the shielding layer 900 and the heat dissipation layer 1000, and between the digitizer 800 and the buffer layer 1100 are not illustrated. However, the present disclosure is not limited thereto. Adhesive layers may also be located between the digitizer 800 and the shielding layer 900, between the shielding layer 900 and the heat dissipation layer 1000, and between the digitizer 800 and the buffer layer 1100.

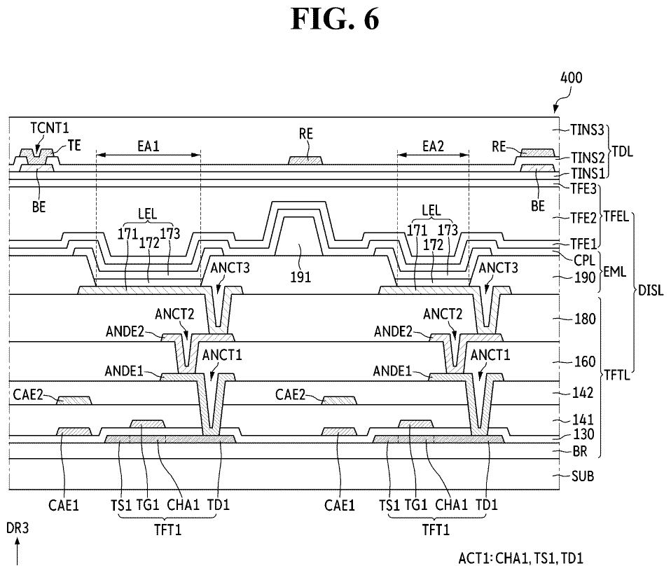

FIG. 6 is a cross-sectional view of an example of a display panel 400 according to one or more embodiments.

Referring to FIG. 6, the display panel 400 may include a substrate SUB, a display layer DISL, and a touch-sensing layer TDL. The display layer DISL may include a thin-film transistor layer TFTL, a light-emitting element layer EML, and an encapsulation layer TFEL.

The substrate SUB may be made of an insulating material, such as polymer resin. For example, the substrate SUB may be made of polyimide. The substrate SUB may be a flexible substrate that can be bent, folded, rolled, and the like.

The thin-film transistor layer TFTL may be located on the substrate SUB. The thin-film transistor layer TFTL may include a barrier layer BR, thin-film transistors TFT1, first capacitor electrodes CAE1, second capacitor electrodes CAE2, first anode connection electrodes ANDE1, second anode connection electrodes ANDE2, a gate-insulating layer 130, a first interlayer insulating layer 141, a second interlayer insulating layer 142, a first planarization layer 160, and a second planarization layer 180.

The barrier layer BR may be located on the substrate SUB. The barrier layer BR is a layer for protecting thin-film transistors of the thin-film transistor layer TFTL and light-emitting layers 172 of the light-emitting element layer EML from moisture introduced through the substrate SUB, which is vulnerable to moisture penetration. The barrier layer BR may be composed of a plurality of inorganic layers stacked alternately. For example, the barrier layer BR may be a multilayer in which one or more inorganic layers selected from a silicon nitride layer, a silicon oxynitride layer, a silicon oxide layer, a titanium oxide layer, and an aluminum oxide layer are alternately stacked.

The thin-film transistors TFT1 may be located on the barrier layer BR. An active layer ACT1 of each of the thin-film transistors TFT1 may be located on the barrier layer BR. The active layer ACT1 of each of the thin-film transistors TFT1 may include polycrystalline silicon, monocrystalline silicon, low-temperature polycrystalline silicon, amorphous silicon, or an oxide semiconductor.

The active layer ACT1 may include a channel region CHA1, a source region TS1, and a drain region TD1. The channel region CHA1 may be a region overlapped by a gate electrode TG1 in the third direction DR3, which is the thickness direction of the substrate SUB. The source region TS1 may be located on a side of the channel region CHA1, and the drain region TD1 may be located on the other side of the channel region CHA1. The source region TS1 and the drain region TD1 may be regions not overlapped by the gate electrode TG1 in the third direction DR3. The source region TS1 and the drain region TD1 may be regions formed to have conductivity by doping a silicon semiconductor or an oxide semiconductor with ions or impurities.

The gate-insulating layer 130 may be located on the active layers ACT1 of the thin-film transistors TFT1. The gate-insulating layer 130 may be made of an inorganic layer, for example, a silicon nitride layer, a silicon oxynitride layer, a silicon oxide layer, a titanium oxide layer, or an aluminum oxide layer.

The gate electrodes TG1 of the thin-film transistors TFT1 and the first capacitor electrodes CAE1 may be located on the gate-insulating layer 130. The gate electrodes TG1 may overlap the channel regions CHA1 in the third direction DR3. Although the gate electrodes TG1 and the first capacitor electrodes CAE1 are spaced apart from each other in FIG. 6, they may also be connected and integrally formed with each other. Each of the gate electrodes TG1 and the first capacitor electrodes CAE1 may be a single layer or a multilayer made of any one or more of molybdenum (Mo), aluminum (Al), chromium (Cr), gold (Au), titanium (Ti), nickel (Ni), neodymium (Nd), copper (Cu), or alloys thereof.

The first interlayer insulating layer 141 may be located on the gate electrodes TG1 of the thin-film transistors TFT1 and the first capacitor electrodes CAE1. The first interlayer insulating layer 141 may be made of an inorganic layer, for example, a silicon nitride layer, a silicon oxynitride layer, a silicon oxide layer, a titanium oxide layer, or an aluminum oxide layer. The first interlayer insulating layer 141 may be composed of a plurality of inorganic layers.

The second capacitor electrodes CAE2 may be located on the first interlayer insulating layer 141. The second capacitor electrodes CAE2 may overlap the first capacitor electrodes CAE1 in the third direction DR3. In addition, when the gate electrodes TG1 and the first capacitor electrodes CAE1 are integrally formed, the second capacitor electrodes CAE2 may overlap the gate electrodes TG1 in the third direction DR3. Because the first interlayer insulating layer 141 has a dielectric constant (e.g., predetermined dielectric constant), capacitors may be formed by the first capacitor electrodes CAE1, the second capacitor electrodes CAE2, and the first interlayer insulating layer 141 located between them. Each of the second capacitor electrodes CAE2 may be a single layer or a multilayer made of any one or more of molybdenum (Mo), aluminum (Al), chromium (Cr), gold (Au), titanium (Ti), nickel (Ni), neodymium (Nd), copper (Cu), or alloys thereof.

The second interlayer insulating layer 142 may be located on the second capacitor electrodes CAE2. The second interlayer insulating layer 142 may be made of an inorganic layer, for example, a silicon nitride layer, a silicon oxynitride layer, a silicon oxide layer, a titanium oxide layer, or an aluminum oxide layer. The second interlayer insulating layer 142 may be composed of a plurality of inorganic layers.

The first anode connection electrodes ANDE1 may be located on the second interlayer insulating layer 142. Each of the first anode connection electrodes ANDE1 may be connected to the corresponding drain region TD1 of a thin-film transistor TFT1 through a first connection contact hole ANCT1 penetrating the gate-insulating layer 130, the first interlayer insulating layer 141, and the second interlayer insulating layer 142. Each of the first anode connection electrodes ANDE1 may be a single layer or a multilayer made of any one or more of molybdenum (Mo), aluminum (Al), chromium (Cr), gold (Au), titanium (Ti), nickel (Ni), neodymium (Nd), copper (Cu), or alloys thereof.

The first planarization layer 160 may be located on the first anode connection electrodes ANDE1 to planarize steps due to the thin-film transistors TFT1. The first planarization layer 160 may be made of an organic layer, such as acryl resin, epoxy resin, phenolic resin, polyamide resin, or polyimide resin.

The second anode connection electrodes ANDE2 may be located on the first planarization layer 160. Each of the second anode connection electrodes ANDE2 may be connected to a first anode connection electrode ANDE1 through a second connection contact hole ANCT2 penetrating the first planarization layer 160. Each of the second anode connection electrodes ANDE2 may be a single layer or a multilayer made of any one or more of molybdenum (Mo), aluminum (Al), chromium (Cr), gold (Au), titanium (Ti), nickel (Ni), neodymium (Nd), copper (Cu), or alloys thereof.

The second planarization layer 180 may be located on the second anode connection electrodes ANDE2. The second planarization layer 180 may be made of an organic layer, such as acryl resin, epoxy resin, phenolic resin, polyamide resin, or polyimide resin.

The light-emitting element layer EML including light-emitting elements LEL and a bank 190 may be located on the second planarization layer 180. Each of the light-emitting elements LEL includes a pixel electrode 171, a light-emitting layer 172, and a common electrode 173.

The pixel electrode 171 may be located on the second planarization layer 180. The pixel electrode 171 may be connected to the corresponding second anode connection electrodes ANDE2 through a third connection contact hole ANCT3 penetrating the second planarization layer 180.

In a top emission structure in which light is emitted from the light-emitting layer 172 toward the common electrode 173, the pixel electrode 171 may be made of a metal material having high reflectivity, such as a stacked structure (Ti/Al/Ti) of aluminum and titanium, a stacked structure (ITO/Al/ITO) of aluminum and indium tin oxide, a stacked structure (ITO/Ag/ITO) of silver and indium tin oxide, an APC alloy, or a stacked structure (ITO/APC/ITO) of an APC alloy and indium tin oxide. The APC alloy is an alloy of silver (Ag), palladium (Pd), and copper (Cu).

The bank 190 may be formed on the second planarization layer 180 to separate the pixel electrodes 171 so as to define emission portions EA1 and EA2. The bank 190 may cover edges of the pixel electrodes 171. The bank 190 may be made of an organic layer, such as acryl resin, epoxy resin, phenolic resin, polyamide resin, or polyimide resin.

Each of a first emission portion EA1 and a second emission portion EA2 is an area in which the pixel electrode 171, the light-emitting layer 172, and the common electrode 173 are sequentially stacked so that holes from the pixel electrode 171 and electrons from the common electrode 173 may recombine together in the light-emitting layer 172 to emit light.

The light-emitting layer 172 may be located on the pixel electrode 171 and the bank 190. The light-emitting layer 172 may include an organic material to emit light of a color (e.g., predetermined color). For example, the light-emitting layer 172 may include a hole-transporting layer, an organic material layer, and an electron-transporting layer.

The common electrode 173 may be located on the light-emitting layer 172. The common electrode 173 may cover the light-emitting layer 172. The common electrode 173 may be a common layer formed commonly in the first emission portion EA1 and the second emission portion EA2.

In the top emission structure, the common electrode 173 may be made of a transparent conductive material (TCO) that can transmit light, such as indium tin oxide (ITO) or indium zinc oxide (IZO), or a semi-transmissive conductive material, such as magnesium (Mg), silver (Ag), or an alloy of Mg and Ag. When the common electrode 173 is made of a semi-transmissive conductive material, light output efficiency may be increased by a microcavity.

A spacer 191 may be located on the bank 190. The spacer 191 may support a mask during a process of manufacturing the light-emitting layers 172. The spacer 191 may be made of an organic layer, such as acryl resin, epoxy resin, phenolic resin, polyamide resin, or polyimide resin.

In some embodiments, the display panel 400 may further include a capping layer CPL located on the common electrodes 173. The capping layer CPL may include an inorganic material. For example, the capping layer CPL may include at least one of silicon nitride, aluminum nitride, zirconium nitride, titanium nitride, hafnium nitride, tantalum nitride, silicon oxide, aluminum oxide, titanium oxide, tin oxide, cerium oxide, or silicon oxynitride.

The encapsulation layer TFEL may be located on the common electrodes 173. The encapsulation layer TFEL may include at least one inorganic layer to reduce or prevent permeation of oxygen or moisture into the light-emitting element layer EML. In addition, the encapsulation layer TFEL may include at least one organic layer to protect the light-emitting element layer EML from foreign substances, such as dust. For example, the encapsulation layer TFEL may include a first encapsulating inorganic layer TFE1, an encapsulating organic layer TFE2, and a second encapsulating inorganic layer TFE3.

The first encapsulating inorganic layer TFE1 may be located on the common electrodes 173, the encapsulating organic layer TFE2 may be located on the first encapsulating inorganic layer TFE1, and the second encapsulating inorganic layer TFE3 may be located on the encapsulating organic layer TFE2. Each of the first encapsulating inorganic layer TFE1 and the second encapsulating inorganic layer TFE3 may be a multilayer in which one or more inorganic layers selected from a silicon nitride layer, a silicon oxynitride layer, a silicon oxide layer, a titanium oxide layer, and an aluminum oxide layer are alternately stacked. The encapsulating organic layer TFE2 may be an organic layer, such as acryl resin, epoxy resin, phenolic resin, polyamide resin, or polyimide resin.

The touch-sensing layer TDL may be located on the encapsulation layer TFEL. The touch-sensing layer TDL may be mounted in the display panel 400 through a continuous process with the display layer DISL. The touch-sensing layer TDL may include a first touch-insulating layer TINS1, connection electrodes BE, a second touch-insulating layer TINS2, driving electrodes TE, sensing electrodes RE, and a third touch-insulating layer TINS3.

The first touch-insulating layer TINS1 may be located on the encapsulation layer TFEL. The first touch-insulating layer TINS1 may be made of an inorganic layer, for example, a silicon nitride layer, a silicon oxynitride layer, a silicon oxide layer, a titanium oxide layer, or an aluminum oxide layer.

The connection electrodes BE may be located on the first touch-insulating layer TINS1. Each of the connection electrodes BE may be a single layer or a multilayer made of any one or more of molybdenum (Mo), aluminum (Al), chromium (Cr), gold (Au), titanium (Ti), nickel (Ni), neodymium (Nd), copper (Cu), or alloys thereof.

The second touch-insulating layer TINS2 may be located on the connection electrodes BE. The second touch-insulating layer TINS2 may be made of an inorganic layer, for example, a silicon nitride layer, a silicon oxynitride layer, a silicon oxide layer, a titanium oxide layer, or an aluminum oxide layer. Alternatively, the second touch-insulating layer TINS2 may be made of an organic layer, such as acryl resin, epoxy resin, phenolic resin, polyamide resin, or polyimide resin.

The driving electrodes TE and the sensing electrodes RE may be located on the second touch-insulating layer TINS2. Each of the driving electrodes TE and the sensing electrodes RE may be a single layer or a multilayer made of any one or more of molybdenum (Mo), aluminum (Al), chromium (Cr), gold (Au), titanium (Ti), nickel (Ni), neodymium (Nd), copper (Cu), or alloys thereof.

The driving electrodes TE and the sensing electrodes RE may overlap the connection electrodes BE in the third direction DR3. Each of the driving electrodes TE may be connected to a connection electrode BE through a touch contact hole TCNT1 penetrating the second touch-insulating layer TINS2.

The third touch-insulating layer TINS3 may be formed on the driving electrodes TE and the sensing electrodes RE. The third touch-insulating layer TINS3 may planarize steps formed by the driving electrodes TE, the sensing electrodes RE, and the connection electrodes BE. The third touch-insulating layer TINS3 may be made of an organic layer, such as acryl resin, epoxy resin, phenolic resin, polyamide resin, or polyimide resin.

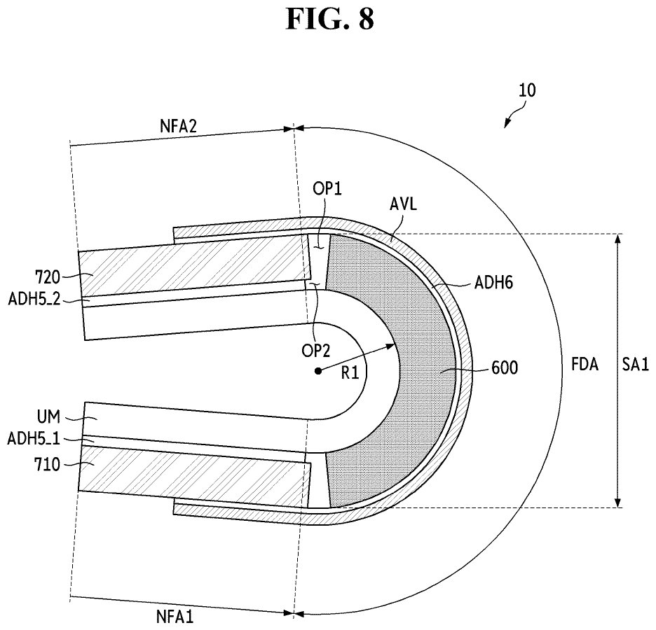

FIG. 7 is an enlarged view of an XA area of FIG. 5. FIG. 8 is a cross-sectional view illustrating a folded state of the display device 10 of FIG. 7.

Referring to FIGS. 7 and 8 in addition to FIG. 5, the support plate 700 may be a separable plate. The support plate 700 may include the first separation space OP1 located between the first support plate 710 and the second support plate 720. The fifth adhesive layer ADH5 may include the second separation space OP2 located between the first sub-adhesive layer ADH5_1 and the second sub-adhesive layer ADH5_2. The first separation space OP1 and the second separation space OP2 may be located side by side in the third direction DR3. The first separation space OP1 and the second separation space OP2 may form an internal space defined by a lower surface of the lower protective layer 510, inner surfaces of the first sub-adhesive layer ADH5_1 and the second sub-adhesive layer ADH5_2 facing each other, inner surfaces of the first support plate 710 and the second support plate 720 facing each other, and an upper surface of the sixth adhesive layer ADH6.

As illustrated in FIG. 8, when the display device 10 is folded, the step compensation film 600 and the lower anti-view layer AVL located in the folding area FDA may be stretched toward the first non-folding area NFA1 and the second non-folding area NFA2. If the first separation space OP1 and the second separation space OP2 are narrow, suitable elongation of the step compensation film 600 and the lower anti-view layer AVL may increase, causing damage to the step compensation film 600 and the lower anti-view layer AVL. Conversely, if the first separation space OP1 and the second separation space OP2 are wide without the step compensation film 600, foreign substances may be introduced, or the folding area FDA may crease due to sagging of the upper module UM.

The display device 10 can reduce the suitable elongation of the step compensation film 600 and the lower anti-view layer AVL by widening the first separation space OP1 and the second separation space OP2 and, at the same time, can reduce or prevent introduction of foreign substances or creasing of the folding area FDA due to sagging of the upper module UM by placing the step compensation film 600 in the first separation space OP1 and the second separation space OP2.

In some embodiments, and referring to FIG. 7, a first width D1 of the first separation space OP1 may be less than a second width D2 of the second separation space OP2. The first width D1 of the first separation space OP1 may be about 1 mm to about 7 mm. The second width D2 of the second separation space OP2 may be about 5 mm to about 15 mm.

A difference between the first width D1 of the first separation space OP1 and the second width D2 of the second separation space OP2 may be equal to the sum of a third width D3 and a fourth width D4. The difference between the first width D1 of the first separation space OP1 and the second width D2 of the second separation space OP2, that is, the sum of the third width D3 and the fourth width D4, may be about 8 mm or less. In some embodiments, sizes of the third width D3 and the fourth width D4 may be equal, but the present disclosure is not limited thereto.

In some embodiments, the step compensation film 600 may be spaced apart from the fifth adhesive layer ADH5 and the support plate 700. In view of an attachment tolerance of the step compensation film 600, a seventh width D7 of the step compensation film 600 may be less than the first width D1 of the first separation space OP1 and the second width D2 of the second separation space OP2. For example, the seventh width D7 of the step compensation film 600 may be about 7 mm or less. A difference between the seventh width D7 of the step compensation film 600 and the first width D1 of the first separation space OP1 may be equal to the sum of a fifth width D5 and a sixth width D6. The difference between the seventh width D7 of the step compensation film 600 and the first width D1 of the first separation space OP1, that is, the sum of the fifth width D5 and the sixth width D6 may be about 1 mm or less. In some embodiments, sizes of the fifth width D5 and the sixth width D6 may be equal, but the present disclosure is not limited thereto.

In the present specification, the first through seventh widths D1 through D7 may refer to lengths in the horizontal direction (e.g., the first direction DR1).

In some embodiments, the second width D2 of the second separation space OP2 may be greater than or equal to a value obtained by multiplying a radius of curvature R1 (e.g., in millimeters (mm)) of the upper module UM by pi (TT). For example, the radius of curvature R1 of the upper module UM may be about 1.5 mm to about 2 mm. Accordingly, the stress generated by the fifth adhesive layer ADH5 when the display device 10 is folded can be reduced or minimized, and the suitable elongation of the step compensation film 600 and the lower anti-view layer AVL can be reduced.

In some embodiments, a third thickness H3 of the step compensation film 600 may be equal to the sum of a first thickness H1 of the fifth adhesive layer ADH5 and a second thickness H2 of the support plate 700. However, the present disclosure is not limited thereto. The third thickness H3 of the step compensation film 600 may also be greater than or equal to the sum of the first thickness H1 of the fifth adhesive layer ADH5 and the second thickness H2 of the support plate 700. For example, the third thickness H3 of the step compensation film 600 may be about 0.8 to about 1.2 times the sum of the first thickness H1 of the fifth adhesive layer ADH5 and the second thickness H2 of the support plate 700. The third thickness H3 of the step compensation film 600 may differ from the sum of the first thickness H1 of the fifth adhesive layer ADH5 and the second thickness H2 of the support plate 700 by about ±50 μm.

Because the step compensation film 600 has flexibility, even if the third thickness H3 of the step compensation film 600 before being bonded is greater than the sum of the first thickness H1 of the fifth adhesive layer ADH5 and the second thickness H2 of the support plate 700, the third thickness H3 of the step compensation film 600 after being bonded may be substantially equal to the first thickness H1 of the fifth adhesive layer ADH5 and the second thickness H2 of the support plate 700.

In addition, even if the third thickness H3 of the step compensation film 600 is less than the sum of the first thickness H1 of the fifth adhesive layer ADH5 and the second thickness H2 of the support plate 700, if the third thickness H3 of the step compensation film 600 is about 0.8 times or more the sum of the first thickness H1 of the fifth adhesive layer ADH5 and the second thickness H2 of the support plate 700, the step compensation film 600 can fully perform the function of supporting the upper module UM.

In the present specification, the first through third thicknesses H1 through H3 may refer to lengths in the vertical direction (e.g., the third direction DR3).

In some embodiments, an elastic modulus of the step compensation film 600 may be about 1 GPa or less. Accordingly, force of restitution due to the step compensation film 600 may be reduced, which, in turn, reduces a vertical distance SA1 between ends of the first support plate 710 and the second support plate 720 after the display device 10 is folded. Therefore, a thickness of the display device 10 while being folded can be reduced.

Hereinafter, other embodiments of the display device 10 will be described. In the following embodiments, the same elements as those of the above-described embodiments will be indicated by the same reference numerals, and their redundant description will be omitted or given briefly, and differences will be mainly described.

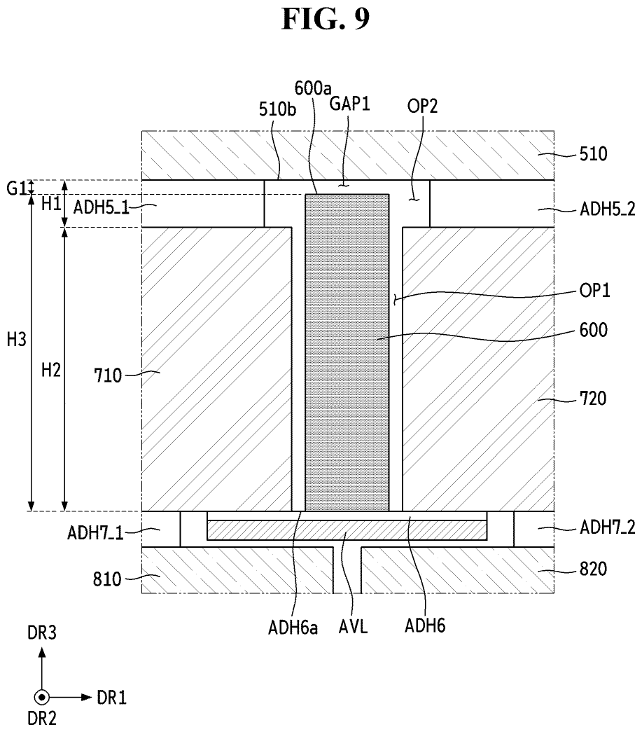

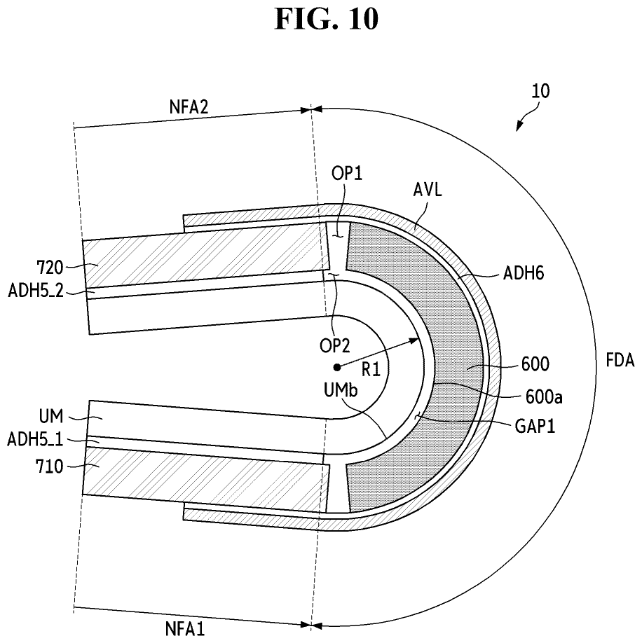

FIG. 9 is a cross-sectional view of a part of a display device 10 according to one or more embodiments. FIG. 10 is a cross-sectional view illustrating a folded state of the display device 10 of FIG. 9.

Referring to FIGS. 9 and 10, the presently described display device 10 is different from the display device 10 of the one or more embodiments corresponding to FIG. 7, etc. in that the display device 10 includes a first gap GAP1 between a step compensation film 600 and a lower protective layer 510.

For example, in the display device 10, the step compensation film 600 may be spaced apart from the lower protective layer 510. For example, the display device 10 may include the first gap GAP1 located between an upper surface 600a of the step compensation film 600 and a lower surface 510b of the lower protective layer 510.

When the step compensation film 600 is spaced apart from the lower protective layer 510, the step compensation film 600 may be bonded to a lower anti-view layer AVL through a sixth adhesive layer ADH6. Accordingly, the step compensation film 600 may be fixed to an upper surface ADH6a of the sixth adhesive layer ADH6.

A thickness G1 of the first gap GAP1 may be about 0.2 times or less the sum of a first thickness H1 of a fifth adhesive layer ADH5 and a second thickness H2 of a support plate 700. The thickness G1 of the first gap GAP1 may be about 50 μm or less.

Due to the first gap GAP1, a third thickness H3 of the step compensation film 600 may be less than the sum of the first thickness H1 of the fifth adhesive layer ADH5 and the second thickness H2 of the support plate 700. Even if the third thickness H3 of the step compensation film 600 is less than the sum of the first thickness H1 of the fifth adhesive layer ADH5 and the second thickness H2 of the support plate 700, if the thickness G1 of the first gap GAP1 is about 0.2 times or less the sum of the first thickness H1 of the fifth adhesive layer ADH5 and the second thickness H2 of the support plate 700, the step compensation film 600 can fully perform the function of supporting an upper module UM.

As illustrated in FIG. 10, because the step compensation film 600 is spaced apart from the upper module UM due to the first gap GAP1, folding stress applied to the upper module UM by the step compensation film 600 can be reduced or minimized.

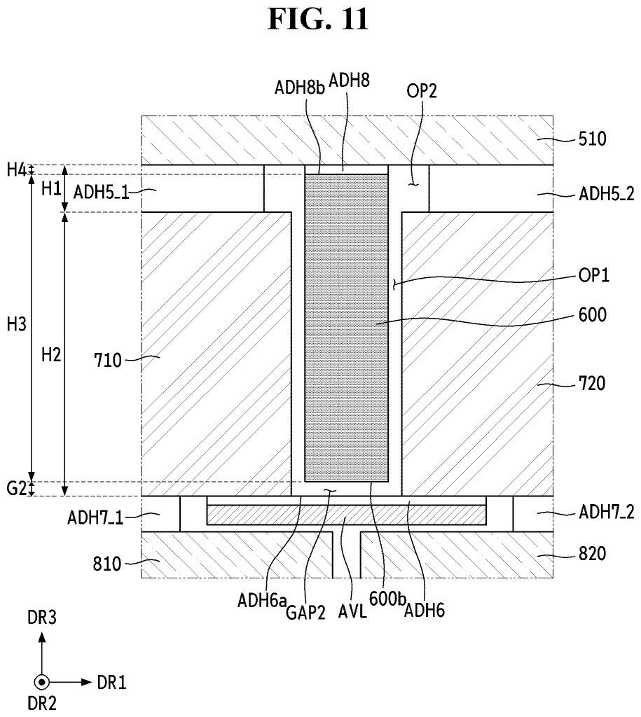

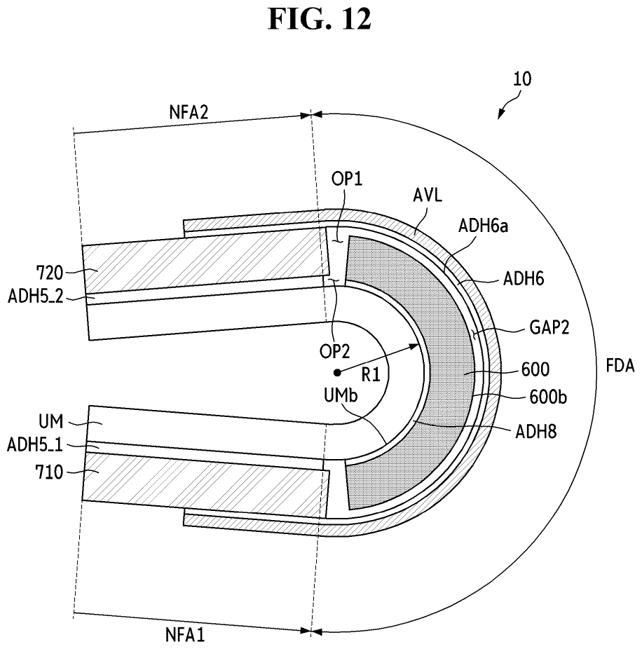

FIG. 11 is a cross-sectional view of a part of a display device 10 according to one or more embodiments. FIG. 12 is a cross-sectional view illustrating a folded state of the display device 10 of FIG. 11.

Referring to FIGS. 11 and 12, the display device 10 is different from the display device 10 according to the one or more embodiments corresponding to FIG. 7, etc. in that the display device 10 includes a second gap GAP2 between a step compensation film 600 and a sixth adhesive layer ADH6 and an eighth adhesive layer ADH8 (e.g., a third adhesive layer in the claims) between the step compensation film 600 and a lower protective layer 510.

For example, in the display device 10, the step compensation film 600 may

be spaced apart from the sixth adhesive layer ADH6. For example, the display device 10 may include the second gap GAP2 located between a lower surface 600b of the step compensation film 600 and an upper surface ADH6a of the sixth adhesive layer ADH6.

The display device 10 may further include the eighth adhesive layer ADH8. The eighth adhesive layer ADH8 may be located under the lower protective layer 510. For example, the eighth adhesive layer ADH8 (e.g., the third adhesive layer in the claims) may be located between the lower protective layer 510 and the step compensation film 600. The lower protective layer 510 and the step compensation film 600 may be bonded to each other through the eighth adhesive layer ADH8. The eighth adhesive layer ADH8 may include a pressure sensitive adhesive or a transparent adhesive, such as an optically clear adhesive. Alternatively, the eighth adhesive layer ADH8 may include an acrylic adhesive material.

When the step compensation film 600 is spaced apart from the sixth adhesive layer ADH6, the step compensation film 600 may be bonded to the lower protective layer 510 through the eighth adhesive layer ADH8. Accordingly, the step compensation film 600 may be fixed to a lower surface ADH8b of the eighth adhesive layer ADH8.

A thickness G2 of the second gap GAP2 may be about 0.2 times or less the sum of a first thickness H1 of a fifth adhesive layer ADH5 and a second thickness H2 of a support plate 700. The thickness G2 of the second gap GAP2 may be about 50 μm or less.

Due to the second gap GAP2 and the eighth adhesive layer ADH8, a third thickness H3 of the step compensation film 600 may be less than the sum of the first thickness H1 of the fifth adhesive layer ADH5 and the second thickness H2 of the support plate 700. Even if the third thickness H3 of the step compensation film 600 is less than the sum of the first thickness H1 of the fifth adhesive layer ADH5 and the second thickness H2 of the support plate 700, if the thickness G2 of the second gap GAP2 is about 0.2 times or less the sum of the first thickness H1 of the fifth adhesive layer ADH5 and the second thickness H2 of the support plate 700, the step compensation film 600 can fully perform the function of supporting an upper module UM.

As illustrated in FIG. 12, because the step compensation film 600 is spaced apart from a lower anti-view layer AVL due to the second gap GAP2, folding stress applied to the lower anti-view layer AVL by the step compensation film 600 can be reduced or minimized.

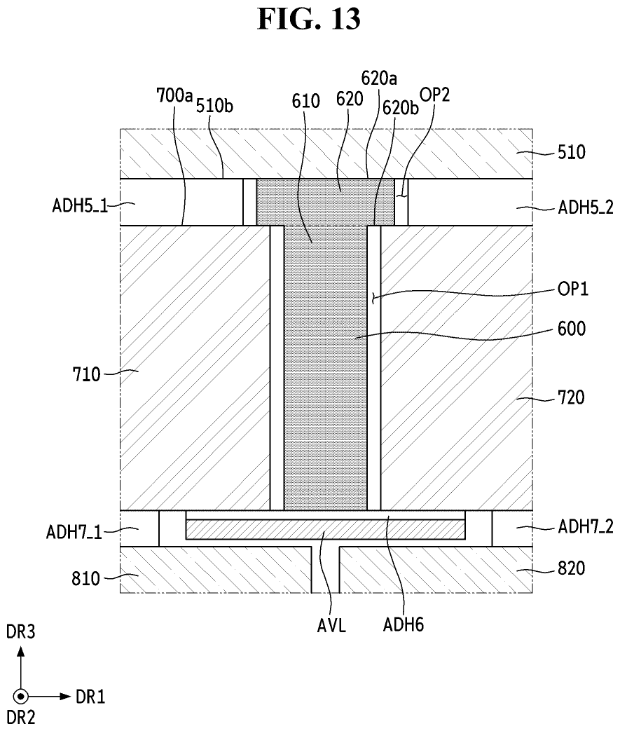

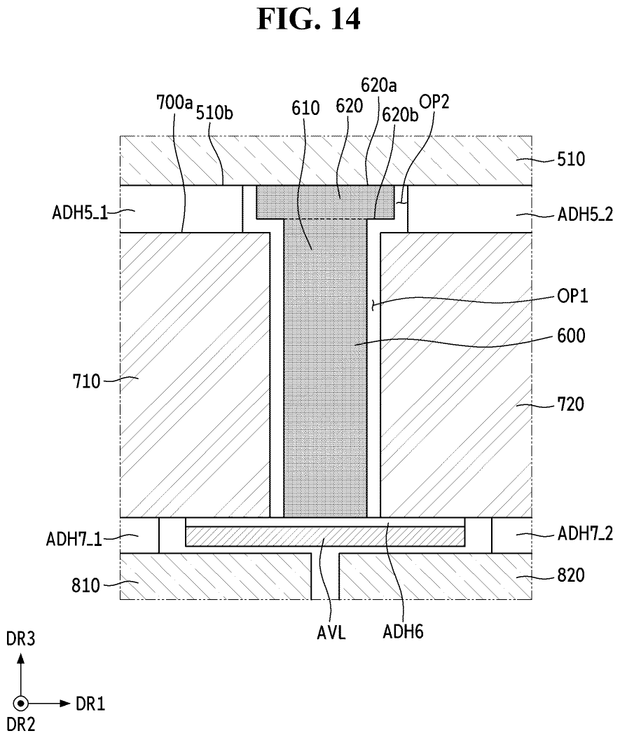

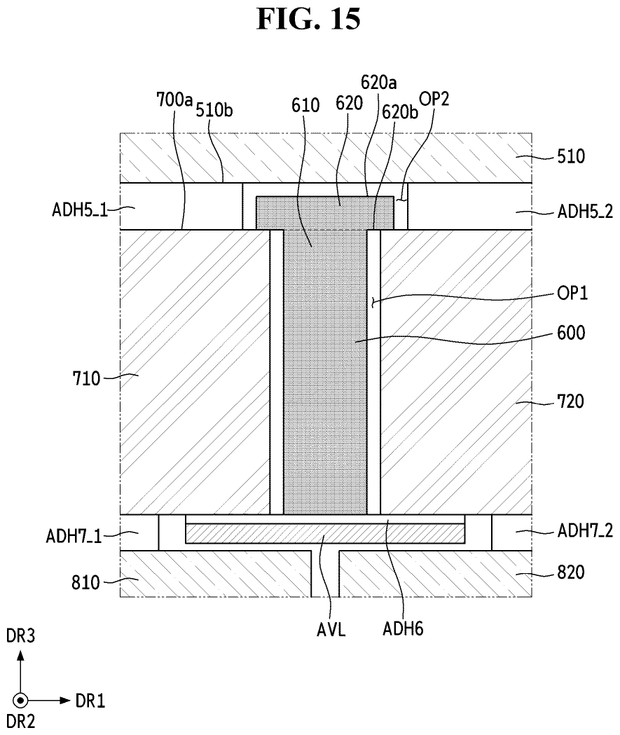

FIG. 13 is a cross-sectional view of a part of a display device according to one or more embodiments. FIG. 14 is a cross-sectional view of a part of a display device according to one or more embodiments. FIG. 15 is a cross-sectional view of a part of a display device according to one or more embodiments.

Referring to FIGS. 13 through 15, a display device 10 is different from the display devices 10 according to the embodiments described above with reference to FIGS. 7, 9, and 11 in the shape of a step compensation film 600.

For example, in the display device 10, the step compensation film 600 may include a first portion 610 extending in the third direction DR3 and a second portion 620 extending in the first direction DR1. The step compensation film 600 may have a T-shape in cross section. For ease of description of the present specification and drawings, the first portion 610 and the second portion 620 are described separately. However, the first portion 610 and the second portion 620 may be a part of a single step compensation film 600 that is physically integrally formed.

The first portion 610 may be located in a first separation space OP1, and the second portion 620 may be located in a second separation space OP2. The second portion 620 may be located on the first portion 610.

In some embodiments, a width of the second portion 620 may be greater than a width of the first portion 610. Accordingly, an area overlapping a lower protective layer 510 (or an upper module UM) located on the separation spaces may be increased. Therefore, even if a width of the second separation space OP2 is greater than a width of the first separation space OP1, a support force for the lower protective layer 510 (or the upper module UM) can be increased because the width of the second portion 620 is greater than the width of the first portion 610.

In one or more embodiments, as illustrated in FIG. 13, an upper surface 620a of the second portion 620 may contact a lower surface 510b of the lower protective layer 510, and a lower surface 620b of the second portion 620 may contact an upper surface 700a of a support plate 700.

In one or more embodiments, as illustrated in FIG. 14, the upper surface 620a of the second portion 620 may contact the lower surface 510b of the lower protective layer 510, and the lower surface 620b of the second portion 620 may be spaced apart from the upper surface 700a of the support plate 700.

In one or more embodiments, as illustrated in FIG. 15, the upper surface 620a of the second portion 620 may be spaced apart from the lower surface 510b of the lower protective layer 510, and the lower surface 620b of the second portion 620 may contact the upper surface 700a of the support plate 700.

In concluding the detailed description, those skilled in the art will appreciate that many variations and modifications can be made to the embodiments without substantially departing from the principles of the present disclosure. Therefore, the disclosed embodiments of the invention are used in a generic and descriptive sense only and not for purposes of limitation.

What is claimed is:

1. A display device comprising:
a display panel comprising a folding area, and a first non-folding area and a second non-folding area on respective sides of the folding area;
a lower protective film below a surface of the display panel;
a support plate below the lower protective film, and comprising a first support plate in the first non-folding area, and a second support plate in the second non-folding area, and defining a first separation space between the first support plate and the second support plate;
a first adhesive layer between the lower protective film and the support plate, and comprising a first sub-adhesive layer overlapping the first support plate, and a second sub-adhesive layer overlapping the second support plate, and defining a second separation space between the first sub-adhesive layer and the second sub-adhesive layer; and
a step compensation film in the first separation space and in the second separation space.

2. The display device of claim 1, wherein a width of the step compensation film is less than a width of the first separation space, and is less than a width of the second separation space.

3. The display device of claim 2, wherein the width of the step compensation film is about 7 mm or less.

4. The display device of claim 2, wherein the width of the first separation space is less than the width of the second separation space.

5. The display device of claim 4, wherein the width of the first separation space is about 1 mm to about 7 mm.

6. The display device of claim 4, wherein the width of the second separation space is about 5 mm to about 15 mm.

7. The display device of claim 4, wherein a difference between the width of the second separation space and the width of the first separation space is about 5 mm or less.

8. The display device of claim 2, wherein a difference between the width of the first separation space and the width of the step compensation film is about 1 mm or less.

9. The display device of claim 1, wherein a thickness of the step compensation film is about 0.8 times to about 1.2 times a sum of a thickness of the first adhesive layer and a thickness of the support plate.

10. The display device of claim 9, wherein a difference between the thickness of the step compensation film and a sum of the thickness of the first adhesive layer and the thickness of the support plate is about 50 mm or less.

11. The display device of claim 1, wherein an elastic modulus of the step compensation film is about 1 GPa or less.

12. The display device of claim 1, further comprising an upper module above the first adhesive layer, and comprising the display panel and the lower protective film, wherein a width of the second separation space is greater than or equal to a value obtained by multiplying a radius of curvature of the upper module by pi.

13. The display device of claim 12, wherein the radius of curvature of the upper module is about 1.5 mm to about 2 mm.

14. The display device of claim 12, further comprising:
a lower anti-view layer above the support plate and in the folding area; and
a second adhesive layer between the lower anti-view layer and the step compensation film.

15. The display device of claim 14, wherein the step compensation film is bonded to the lower anti-view layer through the second adhesive layer.

16. The display device of claim 15, wherein an upper surface of the step compensation film is spaced apart from a lower surface of the lower protective film.

17. The display device of claim 14, further comprising a third adhesive layer between the lower protective film and the step compensation film for bonding the step compensation film to the lower protective film.

18. The display device of claim 17, wherein a lower surface of the step compensation film is spaced apart from an upper surface of the second adhesive layer.

19. The display device of claim 12, wherein the step compensation film comprises a first portion in the first separation space, and a second portion in the second separation space, and
wherein a direction in which the first portion extends is different from a direction in which the second portion extends
wherein a width of the first portion is less than a width of the second portion.

20. An electronic device comprises a display device, the display device comprising:
a display panel comprising a folding area, and a first non-folding area and a second non-folding area on respective sides of the folding area;
a lower protective film below a surface of the display panel;
a support plate below the lower protective film, and comprising a first support plate in the first non-folding area, and a second support plate in the second non-folding area, and defining a first separation space between the first support plate and the second support plate;
a first adhesive layer between the lower protective film and the support plate, and comprising a first sub-adhesive layer overlapping the first support plate, and a second sub-adhesive layer overlapping the second support plate, and defining a second separation space between the first sub-adhesive layer and the second sub-adhesive layer; and
a step compensation film in the first separation space and in the second separation space.
